(19) United States
(12) Patent Application Publication
(10) Pub. No.: US 2024/0241330 A1
(43) Pub. Date: Jul. 18, 2024

(54) Component Carrier With Stack and Optically Transparent Body For Guiding Light

(71) Applicant: AT&S Austria Technologie & Systemtechnik AG, Leoben (AT)

(72) Inventors: Tanja JÖRG, Leoben (AT); Erich SCHLAFFER, St. Lorenzen (AT); Daniel SCHLICK, St. Marein-Feistritz (AT); Heinrich TRISCHLER, Trofaiach (AT)

(21) Appl. No.: 18/410,858

(22) Filed: Jan. 11, 2024

(30) Foreign Application Priority Data
Jan. 12, 2023 (DE) 102023100663.0

(51) Int. Cl. G02B 6/42; H04B 10/40

(52) U.S. Cl. CPC G02B 6/4259; G02B 6/4206; H04B 10/40

(57) ABSTRACT

A component carrier having a stack with at least one electrically conductive layer structure and at least one electrically insulating layer structure, and an at least partially optically transparent body on and/or in the stack, said at least partially optically transparent body being configured to guide light entering from or exiting to an external periphery of the at least partially optically transparent body along a predefined trajectory.

### CROSS-REFERENCE TO RELATED APPLICATIONS

This application claims priority of the filing date of German Patent Application No. 10 2023 100 663.0, filed Jan. 12, 2023, the disclosure of which is incorporated herein by reference in its entirety.

### TECHNICAL FIELD

Embodiments of the disclosure relate to a component carrier and a method of manufacturing a component carrier.

### TECHNOLOGICAL BACKGROUND

In the context of growing product functionalities of component carriers equipped with one or more components and increasing miniaturization of such components as well as a rising number of components to be connected to the component carriers such as printed circuit boards, increasingly more powerful array-like components or packages having several components are being employed, which have a plurality of contacts or connections, with ever smaller spacing between these contacts. In particular, component carriers shall be mechanically robust and electrically reliable so as to be operable even under harsh conditions.

Conventional approaches of forming a package which includes an optical functionality have a high complexity and may suffer from signal distortion.

### SUMMARY

There may be a need to form a compact electro-optical package with high signal integrity.

According to an exemplary embodiment of the disclosure, a component carrier is provided which includes a stack with at least one electrically conductive layer structure and at least one electrically insulating layer structure, and an at least partially optically transparent body on and/or in the stack, said at least partially optically transparent body being configured to guide light entering from or exiting to an external periphery of the at least partially optically transparent body along a predefined trajectory.

According to another exemplary embodiment of the disclosure, a method of manufacturing a component carrier is provided, wherein the method includes providing a stack with at least one electrically conductive layer structure and at least one electrically insulating layer structure, and arranging an at least partially optically transparent body on and/or in the stack, said at least partially optically transparent body being configured to guide light entering from or exiting to an external periphery of the at least partially optically transparent body along a predefined trajectory.

### OVERVIEW OF EMBODIMENTS

In the context of the present application, the term “component carrier” may particularly denote any support structure which is capable of accommodating, directly or indirectly, one or more components thereon and/or therein for providing mechanical support and/or electrical connectivity. In other words, a component carrier may be configured as a mechanical and/or electronic carrier for components. In particular, a component carrier may be one of a printed circuit board, an organic interposer, and an IC (integrated circuit) substrate. A component carrier may also be a hybrid board combining different ones of the above-mentioned types of component carriers.

In the context of the present application, the term “stack” may particularly denote a flat or planar sheet-like body. For instance, the stack may be a layer stack, in particular a laminated layer stack or a laminate. Such a laminate may be formed by connecting a plurality of layer structures by the application of mechanical pressure and/or heat. Preferably, the (in particular laminated) layers may be parallel shifted (in stack thickness direction) in space.

In the context of the present application, the term “layer structure” may particularly denote a continuous layer, a patterned layer or a plurality of non-consecutive islands within a common plane.

In the context of the present application, the term “at least partially optically transparent body” may particularly denote a body arranged on and/or being integrated in a layer stack and comprising at least a portion which allows propagation of light through the body. For instance, the at least partially optically transparent body may be entirely optically transparent, such as glass. It is also possible that part of the at least partially optically transparent body is opaque while another part is transmissive for optical light. The at least partially optically transparent body may be configured for allowing light to propagate from an external periphery via an inlet to an outlet of the at least partially optically transparent body towards a destination. Preferably, the at least partially optically transparent body may be a body (such as a plate or a strip) within which an optically transmissive path is formed along which light can propagate. Such an optically transmissive path may be formed for example by femtosecond-laser processing of the body or by ion exchange technology applied to the body. Hence, there are different ways to form a waveguide in glass, in particular by laser or ion exchange processing. With laser direct writing, also waveguides in a z-direction are possible, which is preferred for exemplary embodiments.

In the context of the present application, the term “light” may particularly denote optical signals in the electromagnetic spectrum having a certain wavelength or wavelength range, for instance in the O-band and/or in the C-band. The O-band is from 1260-1360 nm (including 1310 nm), whereas the C-band is from 1530-1560 nm (including 1550 nm). These ranges cover relevant wavelengths used in optical communications. For example, in some applications, 8 wavelengths per waveguide are used, and for instance up to 32 waveguides. Exemplary embodiments may relate to single-mode waveguides that carry only a single ray of light (i.e., a single mode) or may relate to multimode waveguides that carry multiple rays of light (i.e., multiple modes). For example, the mentioned light may be an optical light beam.

In the context of the present application, the term “predefined trajectory” may particularly denote an optical path inside an at least partially optically transparent body along which light will propagate when entering from an external periphery. Said optical path may be well-defined rather than being arbitrary or random. For instance, the optical path may be defined by total reflection or by reflection to a significant amount of the light when propagating along the predefined trajectory through the at least partially optically transparent body.

In the context of the present application, the term “external periphery” may particularly denote an environment of the at least partially optically transparent body being optically coupled with the latter so that light may enter the at least partially optically transparent body from the environment and/or so that light may exit the at least partially optically transparent body towards the environment. For example, said external periphery may be an optical fiber guiding light and being optically coupled with the at least partially electrically conductive body, for instance by an optical connector. It is however also possible that light propagates through air in the external periphery and is then coupled into the partially optically transparent body.

In the context of the present application, the term “main surface” of a body may particularly denote one of two largest opposing surfaces of the body. The main surfaces may be connected by circumferential side walls. The thickness of a body, such as a stack, may be defined by the distance between the two opposing main surfaces.

According to an exemplary embodiment, a component carrier (such as a printed circuit board or an integrated circuit substrate) of stacked layer type is provided. An at least partially optically transparent body may be mounted on and/or integrated in said layer stack. The light from an external periphery or for transmission to an external periphery may be guided through the optically transparent body along an interior propagation path. By the close spatial relationship between the stack, which may provide an electric functionality, and the optically transparent body, which may provide an optical functionality, a compact electrooptical package with high signal integrity may be obtained. Due to short electric and optical paths in the component carrier, optical and/or electric signals may be transmitted with low loss and high quality.

In the following, further exemplary embodiments of the component carrier and the method will be explained.

In an embodiment, said at least partially optically transparent body comprises an internal portion with a different refraction index with respect to that of a rest of the at least partially optically transparent body, said internal portion being configured to guide the light entering from or exiting to the external periphery of the at least partially optically transparent body along the predefined trajectory. The mentioned internal portion may be a waveguide integrated in the at least partially optically transparent body. Preferably, said internal portion may be written by direct laser writing (for example using a femtosecond-laser) or ion exchange technology into the body. This may allow to create any desired optically transmissive path in an interior of the body. The internal portion may then be formed in a miniature way. It is also possible that the internal portion comprises a plurality of separate optically transmissive paths and/or a bifurcated optically transmissive path. When the internal portion is formed with a different refraction index compared with surrounding material of the body, it may for instance also be possible to ensure that light propagating along the internal portion remains within the internal portion. For instance, the refraction indexes of the internal portion and of the surrounding body portion may be adjusted to achieve total internal reflection at a boundary between said portions. For example, the light guiding internal portion may be straight, curved and/or angled. Furthermore, the light guiding internal portion may have a cylindrical or cuboid shape.

In an embodiment, the method comprises configuring an internal portion of said at least partially optically transparent body as at least one integrated waveguide by laser direct writing. Correspondingly, the internal portion of the component carrier may comprise at least one integrated waveguide formed by laser direct writing in said at least partially optically transparent body. Advantageously, laser direct writing, preferably using a femtosecond laser, in a glass body may allow to form one or a plurality of waveguides which may even be curved.

In an embodiment, the internal portion with the different refraction index defines one or more optical guiding structures exposed to the external periphery of the at least partially optically transparent body. Thus, the optical guiding structure defined by the internal portion may extend from the external periphery into the interior of the component carrier to thereby allow coupling of light from the external periphery into the optical guiding structure and/or from the optical guiding structure towards the external periphery. Preferably, the optically guiding structure of the internal portion in the body may have a second optical interface opposing said external periphery for coupling light into or out of a connected optical member, such as an optical chip. For example, the optical guiding structure may be exposed to the external periphery at a vertical or slanted side wall of the component carrier.

In an embodiment, the internal portion with the different refraction index is configured to guide the light towards a predefined position on an external surface of the at least partially optically transparent body. Hence, the internal portion may be configured for guiding the light along a predefined path to a predefined position. This may ensure an optical transmission with high reliability.

In an embodiment, the at least partially optically transparent body comprises a (for example planar) first surface via which the light enters or exits and a (for example planar) second surface via which the light exits or enters. Due to the internal portion with different refraction index, the light may be guided between the first surface and the second surface. One of the first surface and the second surface may be an optical inlet surface, whereas the other of the first surface and the second surface may be an optical outlet surface. Preferably, the first surface and the second surface of the at least partially optically transparent body may have a low surface roughness Ra (preferably below 50 μm). This may reduce signal losses and ensure reliable signal transmission.

In an embodiment, the first surface and the second surface are perpendicular or inclined with respect to each other. For instance, the first surface may be a vertical surface and the second surface may be a horizontal surface, or vice versa. The vertical surface may be located at a sidewall of the component carrier. The horizontal surface may be located in an interior of the component carrier or at a main surface thereof. This arrangement may require less space and may ensure a compact and highly efficient signal transmission.

In an embodiment, the component carrier comprises a deflecting member configured for deflecting the light after propagation along part of or the entire predefined trajectory. In particular, a deflecting member (which may also be denoted as a diverting member) may be configured for manipulating light by deflection. Such deflection may be at a deflecting surface at which the optical properties change in an abrupt way. For instance, a deflecting surface may be a surface at which the refraction index changes abruptly. A deflecting surface may also be a reflective surface. For instance, a deflecting member may be configured as curved or planar optical mirror, as an optical lens or lens array, etc. The deflecting member may be provided optically downstream of the internal portion with a different refraction index, in particular at an optical outlet of the at least partially optically transparent body (see for example FIG. 2). Additionally or alternatively, a deflecting member may be arranged between at least two sub-portions (in particular between a first sub-portion and a second sub-portion) of the internal portion with the different refraction index (see for example FIG. 1). This may advantageously ensure highly focused signal transmission having complex light guiding geometries.

In an embodiment, the deflecting member is provided in one of the external surfaces of the at least partially optically transparent body. For instance, the deflecting member may be formed at an interface between the at least partially optically transparent body and a surrounding thereof with different refraction index, for instance the stack or a dedicated deflecting element at said interface. Such an embodiment may lead to an easy and highly reliable manufacturing process.

In an embodiment, the deflecting member comprises a reflective portion provided on a surface of the at least partially optically transparent body. Such a reflective portion may be curved or planar. A planar reflective surface may provide reflection of the light only. A curved reflective surface may also provide beam shaping, for instance focusing or defocusing. This may enable a highly reliable article of manufacture for diverse requirements.

In an embodiment, the deflecting member has a surface that is inclined with respect to the light guided by the internal portion with the different refraction index. For instance, the light may propagate along a first direction (for instance horizontally) upstream of the inclined surface and may propagate along a different second direction (for instance vertically) downstream of the inclined surface, or vice versa. Thus, the inclined surface may reflect and/or beam shape the light. Advantageously, this may allow an easy and simultaneously highly reliable light guiding.

In an embodiment, the deflecting member is integrally formed with the at least partially optically transparent body. For instance, the deflecting member may be monolithically integrated with said body. When integrating the deflecting member in the optically transparent body so that the deflecting member forms part of the optically transparent body, the component carrier can be manufactured in a highly compact way. For instance, the deflecting member may be provided with a surface portion treated (for instance polished, curved, etc.) specifically for deflecting light propagating through an internal portion of the body towards said surface portion.

In an embodiment, the deflecting member is provided on a surface of the at least partially optically transparent body. In particular, the deflecting member may be attached to an exterior surface of the at least partially optically transparent body. For instance, such a deflecting member may be configured as a lens member. This may bring the advantage of guiding light towards a destination in a focused manner.

In an embodiment, the deflecting member is configured as a constituent of the at least one electrically conductive layer structure. Thus, the deflecting member may be constituent of at least one electrically conductive layer structure, in particular a metal (for instance copper) trace and/or pillar.

In an embodiment, the deflecting member is configured as alignment marker for ensuring alignment during a manufacturing process. Hence, the deflecting member may further act as alignment marker in the manufacturing process. This may bring the advantage of reduced production stages and/or may ensure compactness.

In an embodiment, the light guided by the internal portion with the different refraction index is emitted towards or received from the deflecting member along a direction that is inclined with respect to a surface of the at least partially optically transparent body via which the light enters or exits and/or with respect to a surface of the at least partially optically transparent body via which the light exits or enters. In particular, a corresponding inclination angle may be 90° or may be different from 90°.

In an embodiment, the internal portion with the different refraction index is configured to separately guide a plurality of light portions or signals simultaneously. For instance, at least 2, in particular at least 5, more particularly at least 10 separate waveguides, may be formed in the interior portion of the at least partially optically transparent body. For instance, up to 32 separate waveguides may be integrated in one optically transparent body. For example, a plurality of separate waveguides structures may be formed as a light guiding internal portion in the body by direct laser writing or ion exchange technology. Each of said integrated waveguides may transport optical signals, in a particular wavelength range (for example the O-band or the C-band), so that the described configuration may significantly increase a data rate of transmitted optical signals.

In an embodiment, there can be a plurality of light signals in one waveguide. Additionally or alternatively, a plurality of waveguides may be formed in the transparent body. It is also possible that a waveguide can transport more than one wavelength simultaneously. For example, a wave-guide channel can carry different wavelengths λ1, λ2, λ3, λ4, etc. (for instance up to 8 wavelengths in the O-band or C-band).

In an embodiment, the component carrier comprises a deflecting member configured for deflecting all the light portions or signals, in particular focusing all the light portions or signals towards a common focus region. Thus, the transmitted optical signals may be bundled for subsequent processing by an optical chip or the like. This may ensure a high-power data transmission.

In an embodiment, the component carrier comprises a focusing unit configured for focusing the light guided by the internal portion with the different refraction index towards a component. For instance, such a focusing unit may be configured as an optical lens or lens array. For example, at least a portion of the component may be in direct contact with at least a portion of the optically transparent body.

More generally, the component carrier may comprise a component mounted on the stack and being in direct contact with at least a portion of the optically transparent body. For instance, this may be done for enabling evanescent light coupling between the component and the optically transparent body. Such an embodiment is shown in FIG. 12. The direct connection between the component, for example an optical chip, and the optically transparent body may lead to a short optical path, to a compact design and to low optical losses as well as to a high signal quality.

In an embodiment, the component carrier has an intermediate space between the at least partially optically transparent body and a component receiving or emitting the light. For instance, such a component may be an optical chip or photonic chip for processing the received light. It is also possible that such a component emits light which is optically coupled into the at least partially optically transparent body via the intermediate space.

In an embodiment, the component carrier comprises a further at least partially optically transparent body arranged in the intermediate space. For example, the further at least partially optically transparent body comprises at least one deflecting member and/or an internal portion with a different refraction index with respect to that of a rest of the further at least partially optically transparent body. One possible aim may be to diverge the light toward a common focus point. For instance, such a further at least partially optically transparent body may be a plate or strip (for example made of glass) with at least one integrated waveguide or another optical member, such as a lens or mirror.

In an embodiment, the intermediate space is an empty space, in particular an air space. For instance, the intermediate space may be an air gap or void volume through which the light may pass. Such an empty space may be shielded against stray light from the environment for further improving signal integrity of an optical signal propagating through the empty space.

In an embodiment, the intermediate space extends from the at least partially optically transparent body to the component receiving or emitting the light. In such a configuration, the optical path may be kept very short, which has a positive impact on signal quality and signal integrity.

In an embodiment, the intermediate space extends along a thickness direction of the stack. Along said thickness direction, the layer structures of the stack may be stacked. For example, the intermediate space may extend through at least part of the stack. This may also contribute to a compact design of the component carrier.

In an embodiment, the intermediate space is formed at least partially by a cavity in the stack. A cavity may be a recess, groove or hole (in particular blind hole) extending into the stack. Preferably, all the sides of the cavity and/or the intermediate space may be defined by the layer structures of the stack.

In an embodiment, the intermediate space is arranged completely inside of the stack. For instance, the intermediate space may be formed as a hollow interior volume being surrounded completely by stack material. This may provide a very reliable protection against stray light, which may further improve optical signal integrity.

In an embodiment, the intermediate space is arranged at least partially outside of the stack. For example, the intermediate space may be arranged completely outside of the stack.

In an embodiment, the component carrier comprises at least one lens arranged in the at least partially optically transparent body and/or in the intermediate space and being configured to change or manipulate a focus of the light. Preferably, the lens is provided downstream of the light guiding structure. Such elements may be arranged for focusing the light onto a light-sensitive surface area, for instance a grating structure on the surface of an optical chip. In particular, the lens may be configured to combine a plurality of light portions or signals to one common light entity (in particular at a certain point, preferably directly on the surface of an optical chip, more specifically to an optical input/output element thereof, see for example reference sign 144 in FIG. 3). This may ensure high performance signal transmission in an easy and reliable manner.

In an embodiment, the component carrier comprises a component (or a plurality of components) configured for receiving or emitting the light and being arranged externally from the stack. Said component may be an optical component.

In an embodiment, the component carrier comprises a component mounted on the stack and being an optical chip. In the context of the present application, the term “optical chip” may particularly denote a chip having an optical functionality. In particular, such an optical chip may be a chip configured for receiving and/or emitting optical signals, and more particularly for converting received optical signals into electric signals by an electrooptical converter (such as a photodiode). The optical chip may also have processing capability for processing optical signals and/or electric signals to or from which the optical signals can be derived by the optical chip. The optical chip may be an electro-optical chip, in particular providing an optical functionality of an electro-optical system. In particular, the optical chip may also have an integrated semiconductor laser diode and/or an amplifier. Hence, examples of integrated circuit elements of an optical chip may be a photodiode and/or a laser diode. For example, integrated group IV devices and/or group III-V devices may be implemented in the optical chip, for example at least one laser, at least one amplifier and/or at least one photodiode. In particular, the optical chip may have waveguide structures integrated to guide the light between different optical elements (like laser diode, photodiode, etc.).

In an embodiment, the component carrier comprises a further component, for example an electric chip or a plurality of electric chips. In the context of the present application, the term “electric chip” may particularly denote a chip having an electric functionality. For example, the electric chip may be configured for processing electric signals, in particular received, from an optical chip. It is also possible that the electric chip comprises a drive functionality, in particular for driving an optical chip. The electric chip may be an electro-optical chip, in particular providing an electric functionality of an electro-optical system. In particular, the electric chip may have amplifying functionality, for instance provided by one or more transimpedance amplifiers (TIAs). When embodied as a transmitter, the electric chip may function as interface between a modulator and its driver. When embodied as receiver, the electric chip may function as interface between the photodiode and an assigned TIA.

In an embodiment, the further component (in particular at least one electric chip) may be electrically coupled with the component (in particular at least one optical chip) by the at least one electrically conductive layer structure of the stack. For example, the at least one electrically conductive layer structure may be configured as a redistribution structure, for instance as a redistribution layer (RDL).

Advantageously, an optical redistribution structure may be formed as a plurality of separated waveguides integrated in an optically transparent body (preferably made of glass). Further advantageously, an electric redistribution structure may be formed as one or a plurality of electrically conductive layer structures on or above the optically transparent body. Such a configuration may allow to obtain very short optical and electrical paths which can be formed with very small dimensions, for instance small pitch.

In an embodiment, the at least partially optically transparent body is arranged in the stack. Preferably, the at least partially optically transparent body is embedded in an interior of the stack. Consequently, the body may be surrounded by stack material but may have two optical interfaces, one with an exterior of the component carrier and the other one with an optical chip.

In an embodiment, the component carrier comprises a component con-figured for receiving or emitting the light and being arranged above (in particular along the stack thickness direction) the at least partially optically transparent body. As mentioned above, said component may be an optical chip. Said component may function as optical receiver component in the described embodiments. However, it is also possible that such a component functions as an optical emitter component for emitting light. Furthermore, the component may also be an optical transceiver component capable of transmitting and receiving optical signals.

In an embodiment, the component carrier comprises a component con-figured for receiving or emitting the light and being arranged laterally from the at least partially optically transparent body. In particular, it may be possible that said component and said body are arranged overlapping one to each other along a direction perpendicular to the stack thickness direction.

In an embodiment, both the at least partially optically transparent body and the component, and optionally the intermediate space, are provided in the stack so that the light is transmitted by the at least partially optically transparent body and is received or emitted by the component from a side facing one to each other. This may lead to a particularly compact configuration of the component carrier and a high signal integrity.

In an embodiment, both the at least partially optically transparent body and the component are at least partially arranged in the same electrically conductive layer structure and/or electrically insulating layer structure of the stack. Hence, at least one component (which may be an optical chip and/or an electric chip) may be embedded in the stack. This may further shorten optical and/or electric signal paths and may therefore improve signal quality.

In an embodiment, the at least partially optically transparent body is made of glass, in particular borosilicate. On the one hand, glass is properly optically transparent and therefore supports high quality optical signal transmission. On the other hand, a glass body may have very flat surfaces (for example having a surface roughness Ra of below 100 nm, preferably below 50 nm) which may allow fine line processing thereon or above it. Furthermore, a glass body may have a high degree of thermal stability so that thermally caused undesired phenomena such as thermal stress, warpage and delamination will not impact the component carrier significantly. Furthermore, glass material may show a low DK and low DF behavior with good dielectric property and may therefore support low loss high-frequency (in particular radio-frequency, RF) and high-speed applications as well as high performance computing application with good signal integrity and low loss.

In another embodiment, the at least partially optically transparent body comprises an organic material, in particular a polymer, more particularly epoxies, modified acrylates, polysiloxanes or organic-inorganic hybrids. An organic material may comprise a chemical compound that contains carbon-hydrogen bonds. For example, the organic body may comprise an organic resin material, an epoxy material, etc.

In an embodiment, the at least partially optically transparent body comprises at least one portion (such as the above-mentioned internal portion of different refraction index) of a material different from a main body (for instance a rest of the transparent body being different from the portion of different reflection index). In particular, a portion of the body may comprise a diverting member or surface which may have differing material properties than the rest of the body.

In an embodiment, the component carrier comprises an optical connector being optically coupled with the at least partially optically transparent body at a sidewall of the component carrier. For instance, an optical wave-guide cable may be connected with said optical connector. Said optical connector may for instance be a fiber connector. It is possible that the optical connector is assembled at a sidewall of the component carrier, for instance at a sidewall of the stack and/or at a sidewall of the at least partially optically transparent body. This may lead to a compact design of the component carrier in vertical direction.

In an embodiment, the at least one electrically conductive layer structure electrically coupling the further component (in particular an electric chip) with the component (in particular an optical chip) is arranged on and/or above the at least partially optically transparent body. In particular, a redistribution structure or a fanout structure may be formed directly on and/or above the optically transparent body. This may shorten the electric signal paths and may therefore improve the signal quality.

In an embodiment, the component carrier comprises a further at least partially optically transparent body on and/or in the stack. The at least one further at least partially optically transparent body may be configured with any feature described herein for the aforementioned at least partially optically transparent body.

In an embodiment, the component carrier comprises a stack of at least one electrically insulating layer structure and at least one electrically conductive layer structure. For example, the component carrier may be a laminate of the mentioned electrically insulating layer structure(s) and electrically conductive layer structure(s), in particular formed by applying mechanical pressure and/or thermal energy. The mentioned stack may provide a plate-shaped component carrier capable of providing a large mounting surface for further components and being nevertheless very thin and compact.

In an embodiment, the component carrier is shaped as a plate. This contributes to the compact design, wherein the component carrier nevertheless provides a large basis for mounting components thereon. In particular, a naked die as (for example) an electronic component can be surface mounted on a thin plate such as a printed circuit board.

In an embodiment, the component carrier is configured as one of the group consisting of a printed circuit board, a substrate (in particular an IC substrate), and an interposer.

In the context of the present application, the term “printed circuit board” (PCB) may particularly denote a plate-shaped component carrier which is formed by laminating several electrically conductive layer structures with several electrically insulating layer structures, for instance by applying pressure and/or by the supply of thermal energy. As preferred materials for PCB technology, the electrically conductive layer structures are made of copper, whereas the electrically insulating layer structures may comprise resin and/or glass fibers, so-called prepreg or FR4 material. The various electrically conductive layer structures may be connected to one another in a desired way by forming holes through the laminate, for instance by laser drilling or mechanical drilling, and by partially or fully filling them with electrically conductive material (in particular copper), thereby forming vias or any other through-hole connections. The filled hole either connects the whole stack, (through-hole connections extending through several layers or the entire stack), or the filled hole connects at least two electrically conductive layers, called via. Similarly, optical interconnections can be formed through individual layers of the stack in order to receive an electro-optical circuit board (EOCB). A printed circuit board is usually configured for accommodating one or more components on one or both opposing surfaces of the plate-shaped printed circuit board. They may be connected to the respective main surface by soldering. A dielectric part of a PCB may be composed of resin with reinforcing fibers (such as glass fibers).

In the context of the present application, the term “substrate” may particularly denote a small component carrier. A substrate may be a, in relation to a PCB, comparably small component carrier onto which one or more components may be mounted and that may act as a connection medium between one or more chip(s) and a further PCB. For instance, a substrate may have substantially the same size as a component (in particular an electronic component) to be mounted thereon (for instance in case of a Chip Scale Package (CSP)). More specifically, a substrate can be understood as a carrier for electrical connections or electrical networks as well as component carrier comparable to a printed circuit board (PCB), however with a considerably higher density of laterally and/or vertically arranged connections. Lateral connections are for example conductive paths, whereas vertical connections may be for example drill holes. These lateral and/or vertical connections are arranged within the substrate and can be used to provide electrical, thermal and/or mechanical connections of housed components or unhoused components (such as bare dies), particularly of IC chips, with a printed circuit board or intermediate printed circuit board. Thus, the term “substrate” also includes “IC substrates”. A dielectric part of a substrate may be composed of resin with reinforcing particles (such as reinforcing spheres, in particular glass spheres).

The substrate or interposer may comprise or consist of at least a layer of glass, silicon (Si) and/or a photoimageable or dry-etchable organic material like epoxy-based build-up material (such as epoxy-based build-up film) or polymer compounds (which may or may not include photo- and/or thermosensitive molecules) like polyimide or polybenzoxazole.

In an embodiment, the at least one electrically insulating layer structure comprises at least one of the group consisting of a resin or a polymer, such as epoxy resin, cyanate ester resin, benzocyclobutene resin, Melamine derivates, Polybenzoxabenzole (PBO), bismaleimide-triazine resin, polyphenylene derivate (e.g. based on polyphenylenether, PPE), polyimide (PI), polyamide (PA), liquid crystal polymer (LCP), polytetrafluoroethylene (PTFE), Bisbenzocyclobutene (BCB) and/or a combination thereof. Reinforcing structures such as webs, fibers, spheres or other kinds of filler particles, for example made of glass (multilayer glass) in order to form a composite, could be used as well. A semi-cured resin in combination with a reinforcing agent, e.g. fibers impregnated with the above-mentioned resins is called prepreg. These prepregs are often named after their properties e.g. FR4 or FR5, which describe their flame-retardant properties. Although prepreg particularly FR4 are usually preferred for rigid PCBs, other materials, in particular epoxy-based build-up materials (such as build-up films) or photoimageable dielectric materials, may be used as well. For high frequency applications, high-frequency materials such as polytetrafluoroethylene, liquid crystal polymer and/or cyanate ester resins, may be preferred. Besides these polymers, low temperature cofired ceramics (LTCC) or other low, very low or ultra-low DK materials may be applied in the component carrier as electrically insulating structures.

In an embodiment, the at least one electrically conductive layer structure comprises at least one of the group consisting of copper, aluminum, nickel, silver, gold, palladium, tungsten and magnesium. Although copper is usually preferred, other materials or coated versions thereof are possible as well, in particular materials coated with supra-conductive material or conductive polymers, such as graphene or poly(3,4-ethylenedioxythiophene) (PEDOT), respectively.

At least one component can be selected from a group consisting of an electrically non-conductive inlay, an electrically conductive inlay (such as a metal inlay, preferably comprising copper or aluminum), a heat transfer unit (for example a heat pipe), a light guiding element (for example an optical waveguide or a light conductor connection), an electronic component, or combinations thereof. An inlay can be for instance a metal block, with or without an insulating material coating (IMS-inlay), which could be surface mounted for the purpose of facilitating heat dissipation. Suitable materials are defined according to their thermal conductivity, which should be at least 2 W/mK. Such materials are often based, but not limited to metals, metal-oxides and/or ceramics as for instance copper, aluminum oxide (Al₂O₃) or aluminum nitride (AlN). In order to increase the heat exchange capacity, other geometries with increased surface area are frequently used as well. Furthermore, a component can be an active electronic component (having at least one p-n-junction implemented), a passive electronic component such as a resistor, an inductance, or capacitor, an electronic chip, a storage device (for instance a DRAM or another data memory), a filter, an integrated circuit (such as field-programmable gate array (FPGA), programmable array logic (PAL), generic array logic (GAL) and complex programmable logic devices (CPLDs)), a signal processing component, a power management component (such as a field-effect transistor (FET), metal-oxide-semiconductor field-effect transistor (MOSFET), complementary metal-oxide-semiconductor (CMOS), junction field-effect transistor (JFET), or insulated-gate field-effect transistor (IGFET), all based on semiconductor materials such as silicon carbide (SiC), gallium arsenide (GaAs), gallium nitride (GaN), gallium oxide (Ga₂O₃), indium gallium arsenide (InGaAs) and/or any other suitable inorganic compound), an optoelectronic interface element, a light emitting diode, a photocoupler, a voltage converter (for example a DC/DC converter or an AC/DC converter), a cryptographic component, a transmitter and/or receiver, an electromechanical transducer, a sensor, an actuator, a microelectromechanical system (MEMS), a microprocessor, a capacitor, a resistor, an inductance, a battery, a switch, a camera, an antenna, a logic chip, and an energy harvesting unit. However, other components may be surface mounted on the component carrier. For example, a magnetic element can be used as a component. Such a magnetic element may be a permanent magnetic element (such as a ferromagnetic element, an antiferromagnetic element, a multiferroic element or a ferrimagnetic element, for instance a ferrite core) or may be a paramagnetic element. However, the component may also be an IC substrate, an interposer, or a further component carrier, for example in a board-in-board configuration. The component may be surface mounted on the component carrier and/or may be embedded therein. Moreover, other components, in particular those components which generate and emit electromagnetic radiation and/or are sensitive with regard to electromagnetic radiation propagating from an environment, may be used as an component.

In an embodiment, the component carrier is a laminate-type component carrier. In such an embodiment, the component carrier is a compound of multiple layer structures which are stacked and connected together by applying a pressing force and/or heat.

After processing interior layer structures of the component carrier, it is possible to cover (in particular by lamination) one or both opposing main surfaces of the processed layer structures symmetrically or asymmetrically with one or more further electrically insulating layer structures and/or electrically conductive layer structures. In other words, a build-up may be continued until a desired number of layers is obtained.

After having completed formation of a stack of electrically insulating layer structures and electrically conductive layer structures, it is possible to proceed with a surface treatment of the obtained layers structures or component carrier.

In particular, an electrically insulating solder resist may be applied to one or both opposing main surfaces of the layer stack or component carrier in terms of surface treatment. For instance, it is possible to form such a solder resist on an entire main surface and to subsequently pattern the layer of solder resist to expose one or more electrically conductive surface portions which shall be used for electrically coupling the component carrier to an electronic periphery. The surface portions of the component carrier remaining covered with solder resist may be efficiently protected against oxidation or corrosion, in particular surface portions containing copper.

It is also possible to apply a surface finish selectively to exposed electrically conductive surface portions of the component carrier in terms of surface treatment. Such a surface finish may be an electrically conductive cover material on exposed electrically conductive layer structures (such as pads, conductive tracks, etc., in particular comprising or consisting of copper) on a surface of a component carrier. If such exposed electrically conductive layer structures are left unprotected, then the exposed electrically conductive component carrier material (in particular copper) might oxidize, making the component carrier less reliable. A surface finish may then be formed for instance as an interface between a surface mounted component and the component carrier. The surface finish has the function to protect the exposed electrically conductive layer structures (in particular copper circuitry) and enable a joining process with one or more components, for instance by soldering. Examples for appropriate materials for a surface finish are Organic Solderability Preservative (OSP), Electroless Nickel Immersion Gold (ENIG), Electroless Nickel Immersion Palladium Immersion Gold (ENIPIG), gold (in particular hard gold), chemical tin, nickel-gold, nickel-palladium, etc.

### BRIEF DESCRIPTION OF THE DRAWINGS

The aspects defined above, and further aspects of the disclosure are apparent from the examples of embodiment to be described hereinafter and are explained with reference to these example embodiments.

FIG. 1 illustrates a cross-sectional view of a component carrier according to an exemplary embodiment of the disclosure.

FIG. 2 illustrates a cross-sectional view of a component carrier according to another exemplary embodiment of the disclosure.

FIG. 3 illustrates a cross-sectional view of a component carrier according to another exemplary embodiment of the disclosure.

FIG. 4 illustrates a cross-sectional view of a component carrier according to another exemplary embodiment of the disclosure.

FIG. 5 illustrates a cross-sectional view of a component carrier according to another exemplary embodiment of the disclosure.

FIG. 6 illustrates a cross-sectional view of a component carrier according to another exemplary embodiment of the disclosure.

FIG. 7 illustrates a cross-sectional view of a component carrier according to another exemplary embodiment of the disclosure.

FIG. 8 illustrates a cross-sectional view of a component carrier according to another exemplary embodiment of the disclosure.

FIG. 9 illustrates a cross-sectional view of a component carrier according to another exemplary embodiment of the disclosure.

FIG. 10 illustrates a cross-sectional view of a component carrier according to another exemplary embodiment of the disclosure.

FIG. 11 illustrates a cross-sectional view of a component carrier according to another exemplary embodiment of the disclosure.

FIG. 12 illustrates a cross-sectional view of a component carrier according to another exemplary embodiment of the disclosure.

### DETAILED DESCRIPTION OF ILLUSTRATED EMBODIMENTS

The illustrations in the drawings are schematically presented. In different drawings, similar or identical elements are provided with the same reference signs.

Before, referring to the drawings, exemplary embodiments will be de-scribed in further detail, some basic considerations will be summarized based on which exemplary embodiments of the disclosure have been developed.

A transition to 100G and 200G electrical lanes may push limits of copper wiring. Doubling a signaling rate to 100 Gbit/s may roughly double the insertion loss for a given length of a low-loss PCB trace. Hence, there may be a need to shorten electrical channels for high-speed data transmission. Current optical transceivers are front panel pluggable modules. With increasing signal speed, there may be a need to shorten the electric and/or optical transmission line length.

According to an exemplary embodiment, a (for instance plate-shaped laminate-type) component carrier (for example a PCB or an IC substrate) is provided which comprises a plurality of stacked metallic and dielectric layer structures. Such a layer stack may have an at least partially optically trans-parent body mounted thereon and/or integrated therein. When light propagates from an external periphery towards the layer stack, or in opposite direction, it may be guided optically through the optically transparent body along a well-defined optical path. Since the described configuration allows to arrange the stack with electric traces spatially close to the optically transparent body with optical signal propagation functionality, a low loss and high-quality transmission of electric and optical signals may be made possible. As a result, electrooptical signals may be transmitted in an efficient and reliable way. This may allow, for example, to place an optical transceiver close to a switch chip, such as an ASIC (application specific integrated circuit). More specifically, an exemplary embodiment of the disclosure provides a package or component carrier with integrated electro-optical functionality for signal transmission from an external optical fiber to an optical chip, and/or vice versa.

For example, a component carrier according to an exemplary embodiment of the disclosure may be embodied as an integrated electro-optical device comprising an optical chip and an electric chip which are disposed side by side on a redistribution layer structure. Said redistribution layer structure may have an opening for providing an optical fiber connection. Furthermore, a waveguide and a mirror may be integrated in the component carrier as well. Beyond this, a glass inlay may be used for providing an optical and preferably also electric functionality.

In particular, a component carrier according to an exemplary embodiment of the disclosure may have an integrated electro-optical device, which may for example comprise a glass inlay or glass core.

Such a component carrier may fulfill one or more optical functions such as in-plane and off-plane coupling between an external fiber and a photonic integrated circuit (PIC), which may also be denoted as an optical chip. Additionally or alternatively, an optical fanout from an external fiber connector to a PIC may be accomplished. It is also possible that waveguide structures (optionally with radius of curvature) are implemented which may function based on a change of a reflective index in glass. In embodiments, an optical mirror and/or a lens may be implemented based on polymer structures on a glass surface (wherein such an optical mirror and/or such a lens may be arranged at a top side and/or at a bottom side of an optically transparent body).

Furthermore, a component carrier according to exemplary embodiments of the disclosure may fulfill one or more electrical functions. This may include the formation of electrical interconnects on a glass surface (for example located at a top side and/or at a bottom side of an optically transparent body). For example, such electrical interconnects may be formed by copper sputtering. Additionally or alternatively, electrical interconnects may be formed in glass of the at least partially optically transparent body, for instance in the form of through glass vias (TGV).

Beyond this, a component carrier according to exemplary embodiments of the disclosure may fulfill one or more mechanical functions. These may include the provision of mechanical stability. Furthermore, structures for mounting a fiber connector may be foreseen.

Optionally, a component carrier according to exemplary embodiments of the disclosure may fulfill one or more additional functions. For example, the component carrier may comprise one or more fiducials for optical alignment. Also features for promoting thermal management may be provided. An electro-magnetic shielding function may be implemented as well, for instance for high-frequency applications. Moreover, one or more barrier layers may be foreseen.

According to an embodiment, a component carrier-type package with integrated electro-optical functionality for signal transmission from an external optical fiber to an optical chip, and vice versa, may be provided. A package with integrated electro-optical functionality may be based on an at least partially optically transparent body which may be embodied as a glass inlay or core. Such an at least partially optically transparent body may contribute to optical and electrical signal transmission combined with optical in-plane and off-plane coupling. A cavity in a redistribution structure or redistribution layer (RDL) may be provided for optical coupling to an optical chip. Advantageously, optical in-plane and off-plane coupling may be combined in one common electro-optical device. In embodiments, an optical signal can be in-plane coupled to an external fiber connector and off-plane coupled to an optical chip (which can be flip-chip assembled in a chip last manufacturing architecture). It is also possible to form an optical fanout from an external fiber array connector with larger pitch to a finer pitch on an optical chip. A further advantage is the possibility to substitute an electrical signal path with an optical signal path. This may allow to reduce insertion loss and power consumption by bit which may ensure high performance. Moreover, a signal path may be formed on glass which may further enhance signal integrity. Apart from this, exemplary embodiments offer a flexible design (for instance what concerns the opportunity to provide one or more electro-optical devices, optical chips, etc.). Further advantageously, the component carrier may be designed so that there is no CTE (coefficient of thermal expansion) mismatch on an optical signal path. When the optical signal is always traveling inside glass material of the at least partially optically transparent body, no inaccuracies due to CTE mismatch may occur. Consequently, there is no risk of degradation of optical performance caused by a CTE mismatch. Furthermore, exemplary embodiments may benefit from advantages of glass, like pronounced mechanical stability, inertness, and ultra-low roughness (which may allow to apply, on glass, fine line traces). Beyond this, a component carrier according to an exemplary embodiment of the disclosure may provide improved optical alignment tolerances due to fiducials which may be formed on the backside of the glass inlay (for instance formed by nanoimprint lithography (NIL) and metallization).

Exemplary applications of exemplary embodiments of the disclosure are co-packaged optics and silicon photonics in data communication and telecommunication applications. This may include the packaging of switches and transceivers for integration in data centers and 5G radio access networks. Moreover, exemplary embodiments of the disclosure are highly appropriate for automotive applications, like lidar, radar, etc. More generally, exemplary embodiments of the disclosure may be implemented advantageously for all applications that need high speed data transmission or high data rate transmission. For example, component carriers according to exemplary embodiments of the disclosure may be employed in data centers. Exemplary embodiments of the disclosure provide a one package technology for multiple applications, such as data communication and telecommunication. Exemplary applications are transceivers, switches, network interfacing cards in data centers and 5G radio access networks, automotive packages, etc.

The package architecture according to exemplary embodiments allows to implement various switches (in particular in form of one or more integrated circuit chips) and transceivers. For example, a component carrier according to exemplary embodiments of the disclosure may be embodied as an ethernet switch or fiber-optic network switch which may be based on switching with an optical-electrical-optical conversion. Such an ethernet switch may be configured as multi-port telecommunication network bridge device connecting multiple optical fibers to each other and controlling data packets routing between inputs and outputs. An ethernet switch may receive a message from a device connected to it and may then transfer the message only to the device for which the message was meant or addressed. A photonic switch or all-optical switch may function by selectively switching an optical signal delivered through an optical fiber or an integrated optical circuitry to another fiber without any electrical data conversion. A photonic switch may route the entire light signal which is coming from an optical input and forward it all to an optical output without converting or altering data packets. An optical transceiver or optical module may have an electrical interface on the side that connects to the inside of the system and an optical interface on the side that connects to the outside world through a fiber-optic cable or the like.

A component carrier-type package according to an exemplary embodiment of the disclosure may include an integrated electro-optical device. The electro-optical device is configured for transmitting an optical signal as well as an electrical signal. The electro-optical device may comprise at least one glass inlay with integrated optically waveguide(s) capable of guiding an optical signal from an external optical fiber, and/or in opposite direction. At least one optical mirror may be provided for off-plane coupling of the signal to an optical chip or photonic integrated circuit. Hence, it may be possible to combine in-plane and off-plane optical coupling in one common electro-optical device. For example, the optical chip may be surface mounted on the integrated electrooptical device (which may be embodied as glass inlay). The electrical interconnections between the optical chip(s) and the electrical chip(s) (which may provide a driver functionality, a transimpedance amplifier functionality, and which may comprise an ASIC) may be realized by direct fanout structures or by building redistribution layers (which may be formed as at least one layer) on top of an electrooptical device layer. This may allow to form a very short electric signal path between the optical chip(s) and the electrical chip(s). When one or more redistribution layers are implemented, a cavity may be formed in the redistribution layers to allow off-plane coupling of an optical signal to a surface mounted optical chip. The latter may be placed for example in the cavity or on top of the redistribution layers. The integration of the electrooptical device in a component carrier-type package may enable optical signal transmission in the package and an optical fanout between the larger pitch of the fiber connector with a finer pitch of the optical chip.

According to a preferred embodiment, a component carrier-type package may be provided with integrated electro-optical device for guiding an optical signal from an optical fiber array connector to optical input/output terminals on one or more optical chips by enabling vertical off-plane coupling. The electrooptical device may comprise one or more glass inlays embedded in the (preferably partially organic) component carrier stack. Said one or more glass inlays may contain one or more optical waveguides for optical signal transmission as well as one or more optical mirrors on the backside for off-plane coupling into the optical chip. Preferably, the one or more optical waveguides may be written by laser direct writing, allowing the formation of three-dimensional waveguide structures. One or more optical mirrors and/or one or more optical alignment fiducials can be realized by nanoimprint lithography (NIL) followed by metallization of the polymer (for example by sputtering). This may lead to a high alignment accuracy. The component carrier may comprise at least one optical chip which may be surface mounted on top of the glass inlay. The electrical interconnections between the at least one optical chip and at least one electric chip may be realized by direct fanout or by using redistribution layers on top of the glass inlay. Advantageously, an optical fanout may be realized from an external fiber array connector to an optical chip. Furthermore, an electrical fanout from the optical chip to one or more electrical chips may be realized as well. Moreover, electrical interconnections may be shortened, and a direct fanout on glass may enhance signal integrity.

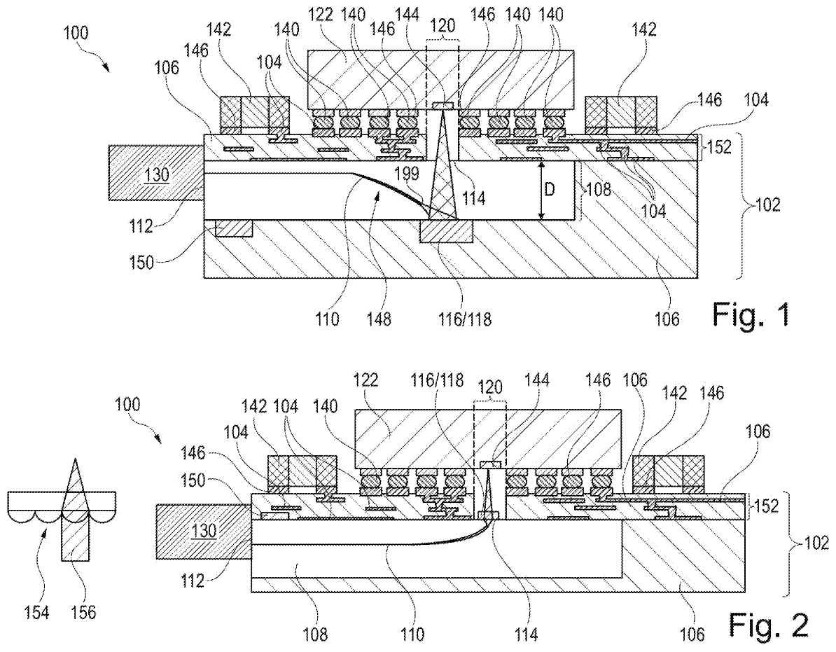

FIG. 1 illustrates a cross-sectional view of a component carrier 100 according to an exemplary embodiment of the disclosure.

The illustrated component carrier 100 (such as a printed circuit board or an integrated circuit substrate) comprises a component 122 mounted by a connection structure 140 (such as solder bumps) on a layer stack 102. As shown, also other components 142 are surface mounted on the stack 102. Additionally or alternatively to the surface mounted component 122, 142, it is also possible to embed one or more components 122, 142 in the stack 102 (not shown). In the shown embodiment, component 122 is an optical chip (or photonic chip) having one or more optical input and/or output elements 144. For example, such an optical chip may convert a received optical signal into an electrical signal, and/or may convert an electrical signal into an optical signal to be transmitted. Such an optical chip may comprise for example one or more photodiodes, a multiplexer, a processor, etc. Components 142 may be embodied as passive components, such as capacitors or inductors. Each of components 122, 142 may have one or more electric connection pads 146 for establishing an electrically conductive connection with electrically conductive layer structures 104 of stack 102.

For example, the component carrier 100 may comprise a laminated layer stack 102 comprising a plurality of electrically conductive layer structures 104 and of electrically insulating layer structures 106. The electrically conductive layer structures 104 may comprise patterned copper layers which may form horizontal pads and/or a horizontal wiring structure. Additionally or alternatively, the electrically conductive layer structures 104 may comprise vertical through connections such as copper pillars and/or copper filled laser vias. Moreover, the stack 102 of the component carrier 100 may comprise one or more electrically insulating layer structures 106 (such as prepreg or resin sheets). Also surface finish (like ENIG or ENEPIG, a solder resist, etc.) may be optionally applied on the top side and/or on the bottom side of the stack 102.

Surface mounted component 122 being configured for receiving the light is arranged externally from the stack 102 and above a below described optically transparent body 108. The component 122 is here configured as bare die (i.e. non-encapsulated semiconductor chip) and is surface mounted on a top main surface of the stack 102. The component 122 may be configured as semiconductor chip, for instance active semiconductor chip. Examples of the IC-type component 122 are an optical transmitter chip, an optical receiver chip, and an optical transceiver chip. The component 122 may comprise an integrated circuit with at least one monolithically integrated circuit element, such as a photodiode and/or transistors, in an active region. The component 122 can also be a stacked IC, a module, a chiplet, or a system-on-chip (SoC).

For improving alignment of the component 122, one or more fiducials 150 may be foreseen. For instance, at least one fiducial 150 may be embedded in stack 102, for example at the bottom side of the optically transparent body 108.

Still referring to FIG. 1, the component carrier 100 comprises optically transparent body 108 integrated or embedded in the stack 102. The optically transparent body 108 may be a glass body, for instance a glass strip made of borosilicate. For example, the optically transparent body 108 may have a thickness D in a range from 0.05 mm to 2 mm, for instance 0.5 mm. In the shown embodiment, the optically transparent body 108 is a glass inlay which is embedded in the stack 102. Alternatively, the optically transparent body 108 can be a central core of stack 102 on which layer build-ups can be formed and/or through which electrically conductive structures may extend.

The optically transparent body 108 is configured to guide light (preferably infrared light, wherein visible light, UV light, etc., may be possible as well) entering from an external periphery of the optically transparent body 108 along a predefined trajectory. For this purpose, the optically transparent body 108 comprises an internal portion 110 with a different refraction index with respect to that of the rest of the optically transparent body 108. Descriptively speaking, the internal portion 110 may be a light guiding structure along which the light propagates when entering through one of surfaces 112, 114 described below in further detail. Also, a plurality of light guiding structures may be implemented, so that more generally one or more light guiding structures are possible in the transparent body 108. Preferably, the internal portion 110 may be formed by direct laser writing in the optically transparent body 108 made of glass. In this way, it is advantageously possible to even form a curved internal portion 110 along which the light is guided. Hence, said internal portion 110 may be configured to guide the light entering from the external periphery of the optically transparent body 108 along the predefined trajectory and thus in a well-defined way. As shown, the internal portion 110 with the different refraction index extends along an uninterrupted path between exposed surfaces 112, 114 in different regions of the optically transparent body 108 and thereby defines an optical guiding structure exposed to the external periphery of the optically trans-parent body 108 at two opposing ends. In this way, the internal portion 110 with the different (or locally varying) refraction index is configured to guide the light towards a predefined position on an external surface of the optically transparent body 108. For instance, a curved section of the internal portion 110 may have a radius of curvature (RoC) in a range from 10 mm to 20 mm, see reference sign 148 in FIG. 1.

As shown in FIG. 1, there is the possibility that at a certain point the light (for instance a light beam) propagating along the internal portion 110 will become broader (or narrower). In FIG. 1, the light becomes broader after the kink of the internal portion 110.

In the shown embodiment, the optically transparent body 108 comprises a planar vertical first surface 112 via which the light enters from a connected optical connector 130 (such as a fiber connector). Optical coupling via first surface 112 may be in-plane coupling. Moreover, the optically transparent body 108 comprises a planar horizontal second surface 114 via which the light exits into an intermediate space 120 (embodied as an air gap in an interior of component carrier 100) and from here to the optical input and/or output element 144 of the optical chip-type component 122. Optical coupling via second surface 114 may be out-plane coupling. A skilled person will understand that the optical path according to FIG. 1 can be inverted, i.e. light may be emitted by component 122 and may be transmitted through the optically transparent body 108 to the optical connector 130. For instance, coupling an optical signal between optical connector 130 and the first surface 112 of the optically transparent body 108 may be accomplished by edge coupling, grating coupling, or in another way. The optical connector 130 may be connected sideways, i.e., on a side wall of component carrier 100. Alternatively, the optical connector 130 may be connected horizontally, i.e., on a horizontal main surface of component carrier 100.

Since the first surface 112 is formed as a vertical area and the second surface 114 is formed as a horizontal area, the surfaces 112, 114 are perpendicular with respect to each other. The conversion between a horizontally propagating light and a vertically propagating light may be accomplished by a functional cooperation of the curved integrated optical waveguide of the internal portion 110 and a deflecting member 116 connected to an exterior surface of the optically transparent body 108. According to FIG. 1, the deflecting member 116 is configured for deflecting the light after propagation along part of the predefined trajectory. As already mentioned, the deflecting member 116 of FIG. 1 is attached to an external surface of the optically transparent body 108. In the shown embodiment, the deflecting member 116 comprises a reflective portion provided on an exterior surface of the optically transparent body 108. Thus, the deflecting member 116 is provided on a surface of the optically transparent body 108. To put it shortly, the deflecting member 116 of FIG. 1 is embodied as an optical mirror providing beam reflection for off-plane coupling. More specifically, the light coupled into the optically transparent body 108 via first surface 112 is guided first through a straight (for example horizontal) section and subsequently through a curved section of the internal portion 110, before being reflected at the deflecting member 116 from where the light is focused onto the optical input and/or output element 144 of component 122. In order to provide such a focusing function, the reflective surface of the deflecting member 116 may be curved. Thus, the deflecting member 116 may also function as focusing unit 118 configured for focusing the light guided by the internal portion 110 with the different refraction index towards component 122. Again, referring to FIG. 1, the light guided from the internal portion 110 with the different refraction index is emitted to-wards the deflecting member 116 along a direction that is inclined with respect to the first surface 112 of the optically transparent body 108 via which the light is entered. Furthermore, the light is emitted towards the deflecting member 116 along a direction that is inclined with respect to the second surface 114 of the optically transparent body 108 via which the light is exiting.

For instance, it may be possible that the optical light beam starts to spread apart at a predefined point, see for example reference sign 199 in FIG. 1. Also preferably, the spatial way of the light from the first surface 112 and the deflecting member 116 may be longer than the spatial way of the light from the deflecting member 116 to the second surface 114. For example, the horizontal way may be longer than the vertical way, for instance if the optically transparent body 108 (in particular a glass plate) is rather thin.

As already mentioned, component carrier 100 of FIG. 1 has intermediate space 120 between the optically transparent body 108 and the component 122 receiving the light. According to FIG. 1, the intermediate space 120 is an empty air space. As shown, the intermediate space 120 extends from the optically transparent body 108 up to the component 122 receiving the light and is laterally confined by stack 102. The intermediate space 120 extends along a thickness direction of part of the stack 102 and is formed by a cavity in the stack 102. Thus, the intermediate space 120 is arranged partially inside of the stack 102. The cavity formed in stack 102 thereby contributes to the optical coupling.

Furthermore, a top-sided portion of stack 102 formed partially on the optically transparent body 108 and comprising at least some of the electrically conductive layer structures 104 may form an electrical interface for electrically coupling the component 122 and the other components 142. This top-sided portion of stack 102 constitutes a redistribution structure 152 formed in part directly on top of the optically transparent body 108. This contributes to a shortening of the electric signal paths. Furthermore, the very smooth surface of the glass body is compatible with fine lines structuring directly thereon.

Since proper adhesion may be challenging on smooth surfaces, an adhesion promoter may be applied to the optically transparent body 108 and/or the electrically insulating layer structure 106 and/or the electrically conductive layer structure 104 and/or a redistribution structure or redistribution layer (RDL). In particular, adhesion between different electrically insulating structures of the component carrier 100 may be improved in this way.

Advantageously, the embodiment of FIG. 1 accomplishes in-plane and off-plane coupling. The component carrier 100 according to FIG. 1 provides a package with electrooptical device. Optically transparent body 108 made of glass (and being configured as inlay or core) may be provided with one or more integrated optical waveguides and one or more optical members (for example a mirror) for off-plane coupling to a surface mounted optical chip (or photonic integrated circuit, PIC). Moreover, electrical interconnects in the form of a redistribution structure or redistribution layer (RDL) to one or more electrical chips (for instance including a driver, a TIA, an ASIC) may be provided as well. A cavity in the RDL may serve for optically coupling the glass body to the optical chip.

FIG. 2 illustrates a cross-sectional view of a component carrier 100 according to another exemplary embodiment of the disclosure.

The embodiment according to FIG. 2 differs from the embodiment according to FIG. 1 in particular in that, according to FIG. 2, a deflecting member 116 is located inside intermediate space 120 and on the top surface of the optically transparent body 108. Said deflecting member 116 may be embodied as optical microlens array. The deflecting member 116 according to FIG. 2 may also function as a focusing unit 118 for focusing the light propagating outwardly through the second surface 114 towards the at least one optical input and/or output element 144 for detection by optical component 122. A detail 154 in FIG. 2 illustrates an optical microlens array, as an embodiment for a deflecting member 116 being configured as focusing unit 118 and being manufacturable in nanoimprint lithography (NIL) technology. Said detail 154 also illustrates focusing of light 156. Hence, deflecting member 116 of FIG. 2 may be embodied as shown in detail 154.

According to FIG. 2, an alignment fiducial 150 may be formed on the top side rather than on the bottom side of the optically transparent body 108.

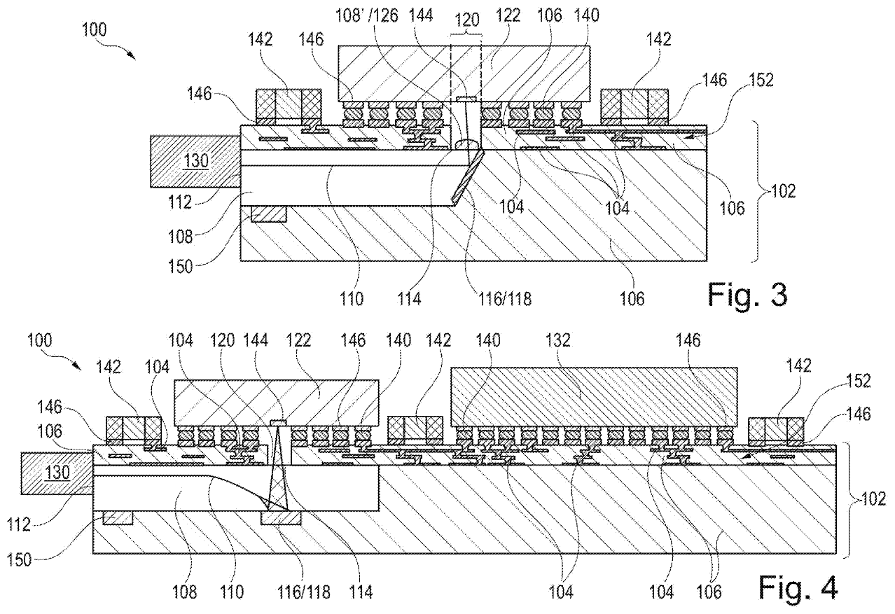

FIG. 3 illustrates a cross-sectional view of a component carrier 100 according to another exemplary embodiment of the disclosure.

The embodiment according to FIG. 3 differs from the embodiment according to FIG. 1 in particular in that, according to FIG. 3, a convex lens 126 is arranged on the optically transparent body 108 and in the intermediate space 120 and is configured to change or manipulate a focus of the light. Said lens 126 may be configured as further optically transparent body 108′ arranged on top of the optically transparent body 108. Furthermore, the embodiment of FIG. 3 is equipped with a deflecting member 116 in form of an inclined reflective surface (for instance a metallic surface, such as a metallized slanted sidewall of the optically transparent body 108). Said reflective surface is inclined with respect to the impinging light guided by the internal portion 110 with the different refraction index. Consequently, the reflective surface redirects the light from its horizontal propagation direction into a vertical propagation direction towards lens 126 and from there to the at least one optical input and/or output element 144 of optical component 122. Descriptively speaking, the optical mirror provides an optical reflection for off-plane coupling. When the reflective surface of the deflecting member 116 is curved, it may function as well as a focusing unit 118 for focusing the light towards lens 126.

FIG. 4 illustrates a cross-sectional view of a component carrier 100 according to another exemplary embodiment of the disclosure.

The embodiment according to FIG. 4 differs from the embodiment according to FIG. 1 in particular in that, according to FIG. 4, a further component 132 being embodied as an electric chip is surface mounted on the stack 102 and is electrically coupled with the component 122, embodied as optical chip, by electrically conductive layer structures 104 configured as a redistribution structure 152. As shown, the electrically conductive layer structures 104 electrically coupling the further component 132 with the component 122 are arranged partially on and partially above the optically transparent body 108. For instance, the further component 132 may be embodied as ASIC chip, for instance ASIC switch. The further component 132, embodied as an electric chip, may also be embedded in stack 102 rather than being surface mounted thereon.

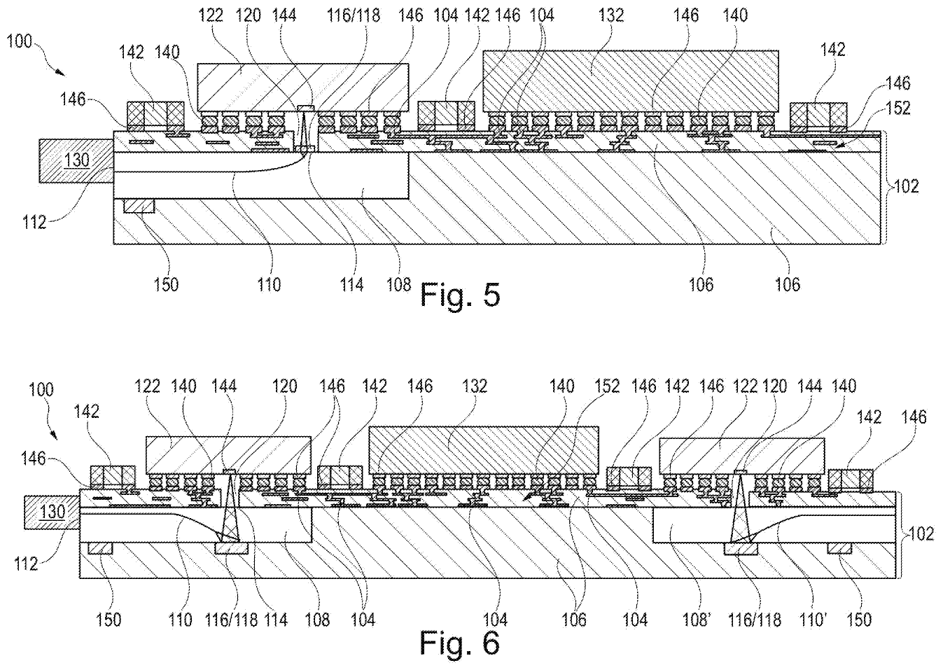

FIG. 5 illustrates a cross-sectional view of a component carrier 100 according to another exemplary embodiment of the disclosure.

The embodiment according to FIG. 5 differs from the embodiment according to FIG. 4 in particular in that, according to FIG. 5, a deflection member 116 and/or focusing unit 118 is additionally provided on the second surface 114 of the optically transparent body 108 and in the intermediate space 120 (as in FIG. 2). For example, said deflection member 116 and/or focusing unit 118 may be embodied as optical microlens array, as described above referring to FIG. 2.

FIG. 6 illustrates a cross-sectional view of a component carrier 100 according to another exemplary embodiment of the disclosure.

The embodiment according to FIG. 6 differs from the embodiment according to FIG. 4 in particular in that, according to FIG. 6, a further optically transparent body 108′ is integrated or embedded in the same stack 102 as optically transparent body 108 and is optically coupled with an additional surface mounted component 122, such as a further optical chip. Also, the further optically transparent body 108′ comprises an internal portion 110′ with a different refraction index with respect to that of a rest of the further optically transparent body 108′. To put it shortly, construction of the further optically transparent body 108′ may be the same as the construction of the optically transparent body 108.

Hence, an even more complex electrooptical functionality may be integrated in component carrier 100 according to FIG. 6.

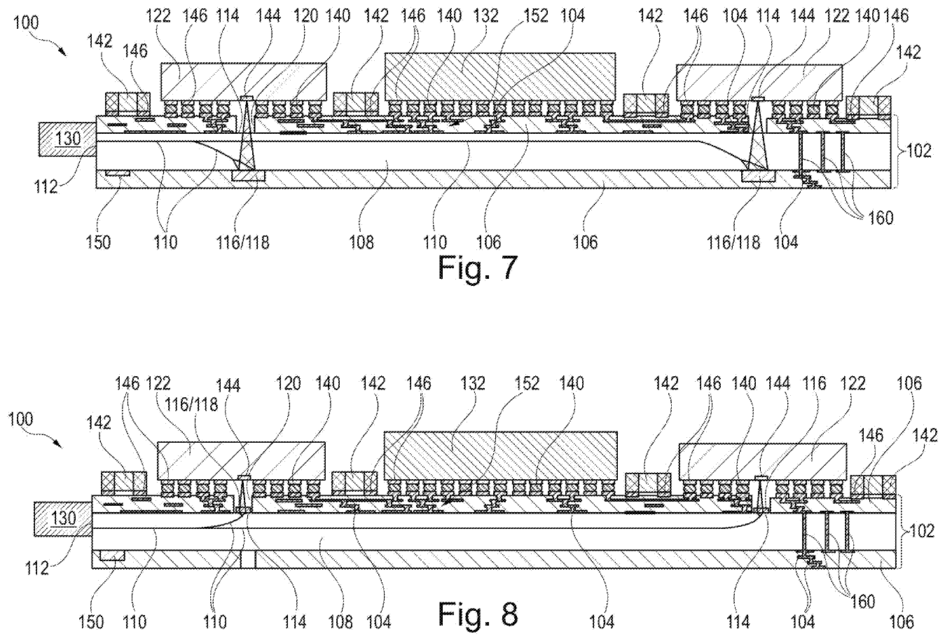

FIG. 7 illustrates a cross-sectional view of a component carrier 100 according to another exemplary embodiment of the disclosure.

The embodiment according to FIG. 7 differs from the embodiment according to FIG. 6 in particular in that, according to FIG. 7, the internal portion 110 with the different refraction index is configured to separately guide a plurality of light simultaneously. In other words, a plurality of separate optical waveguides may be integrated in a single optically transparent body 108. Thus, the functionality of the two separate optically transparent bodies 108, 108′ according to FIG. 6 is provided by a single common optically transparent body 108 in FIG. 7. For each of the different integrated waveguides of internal portion 110 of optically transparent body 108, a separate surface mounted component 122 (each embodied as optical chip) may be provided. The optical chip-type components 122 may for instance share a common further component 132, such as a common electric chip. Furthermore, for each of the different integrated waveguides of internal portion 110 of optically transparent body 108, a separate deflecting member 116 (for instance simultaneously providing a focusing function and thereby being configured as focusing unit 118) may be provided for deflecting all the light towards a respectively assigned component 122. Multiple integrated waveguides as internal portion 110 of a common optically transparent body 108 may be formed for instance by laser direct writing.

Referring to FIG. 7, one or more electrically conductive vertical through connections 160 may be formed to extend vertically through the entire optically transparent body 108 (preferably made of glass). In particular, said vertical through connections 160 may be through glass vias (TGVs), which may be made for example of copper. Said vertical through connections 160 may electrically couple electrically conductive layer structures 104 of stack 102 above and below the optically transparent body 108 with each other.

FIG. 8 illustrates a cross-sectional view of a component carrier 100 according to another exemplary embodiment of the disclosure.

The embodiment according to FIG. 8 differs from the embodiment according to FIG. 7 in particular in that, according to FIG. 8, two respective deflecting members 116 are located inside a respective intermediate space 120 and on the top surface of the optically transparent body 108. Said deflecting members 116 may be embodied as optical microlens arrays, as described above referring to FIG. 2.

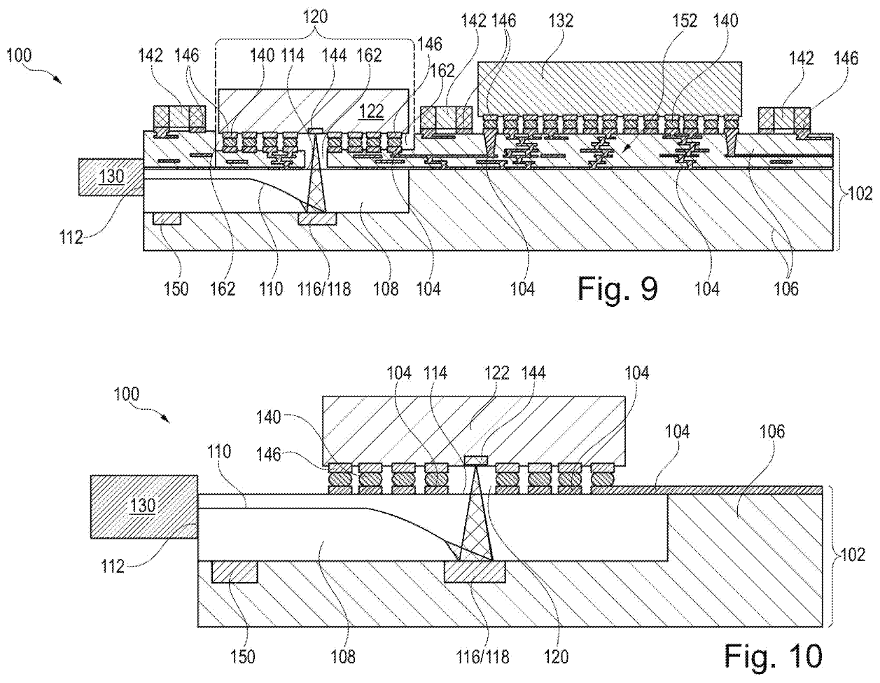

FIG. 9 illustrates a cross-sectional view of a component carrier 100 according to another exemplary embodiment of the disclosure.

The embodiment according to FIG. 9 differs from the embodiment according to FIG. 4 in particular in that, according to FIG. 9, component 122 is embedded partially in cavity 162 formed in the portion of the stack 102 above the optically transparent body 108. This may render component carrier 100 according to FIG. 9 highly compact in vertical direction.

FIG. 10 illustrates a cross-sectional view of a component carrier 100 according to another exemplary embodiment of the disclosure.

The embodiment according to FIG. 10 differs from the embodiment according to FIG. 1 in particular in that, according to FIG. 10, an electrical coupling of the surface mounted component 122 is accomplished by a single patterned metal layer arranged partially directly on the optically transparent body 108 and partially on a dielectric surface of stack 102. An electrical interface of the component carrier 100 according to FIG. 10 may be accomplished by a direct fanout or a single redistribution layer (RDL). This may lead to a particularly compact design of the component carrier 100 of FIG. 10.

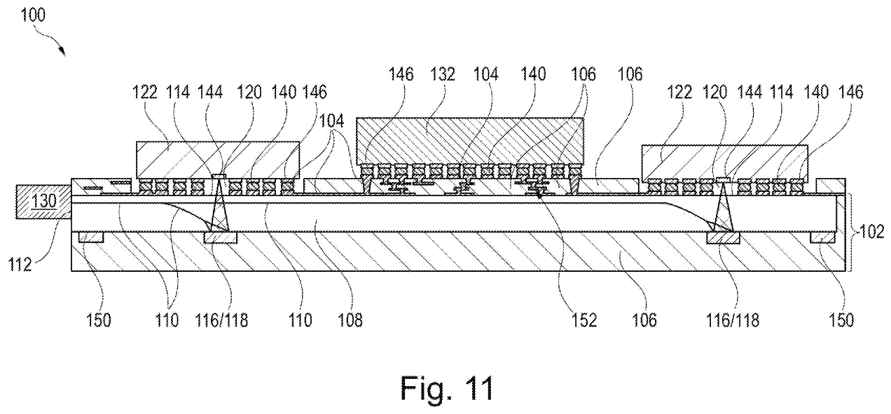

FIG. 11 illustrates a cross-sectional view of a component carrier 100 according to another exemplary embodiment of the disclosure.

The embodiment according to FIG. 11 differs from the embodiment according to FIG. 7 in particular in that, according to FIG. 11, the vertical through connections 160 extending through the optically transparent body 108 are omitted. Furthermore, no passive components 142 are foreseen according to FIG. 11.

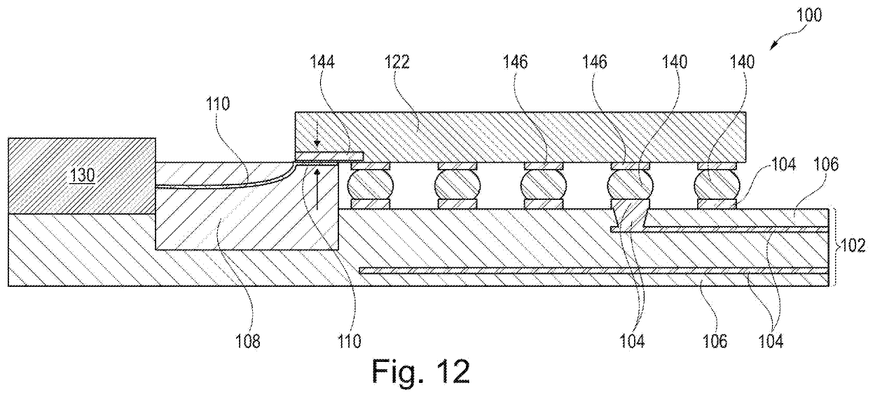

FIG. 12 illustrates a cross-sectional view of a component carrier 100 according to another exemplary embodiment of the disclosure.

According to FIG. 12, the illustrated component carrier 100 has a surface mounted component 122, here embodied as an optical chip, which is assembled on top of stack 102. Furthermore, component 122 is in direct contact with a portion of the optically transparent body 108. Due to the direct physical connection between the component 122 and the optically transparent body 108, light can be efficiently coupled between optical input and/or output element 144 of component 122 and internal portion 110 of optically transparent body 108. As shown, optical input and/or output element 144 and an interface section of internal portion 110 may directly face each other. This may lead to a short optical path, to a compact design and to low optical losses as well as to a high signal quality.

Descriptively speaking, FIG. 12 may provide a package-type component carrier 100 with integrated electro-optical device for signal transmission from an external optical fiber to an optical chip, and/or vice versa. Furthermore, a glass inlay or glass substrate with integrated optical waveguide(s) may be foreseen as optically transparent body 108 with internal portion 110. Moreover, a cavity may be formed in stack 102 for embedding part of optically transparent body 108, here embodied as glass inlay. Furthermore, an electrical interconnection to one or more electrical chips (such as a driver, a TIA, an ASIC, etc.) may be established (not shown in FIG. 12).

Furthermore, light coupling may be realized by evanescent coupling. In the shown embodiment, an SOI (silicon on insulator) waveguide (in the component 122, here embodied as a photonic IC) may be in direct contact with the waveguide in the glass, i.e., with internal portion 110 of optically transparent body 108. The SOI waveguide in the optical chip is thus in close contact with the glass waveguide allowing evanescent field coupling of the light. Descriptively speaking, surrounding glass may act as cladding. When the waveguide is written not in the glass core, but on the glass surface, the light can tunnel to the waveguide on the optical chip.

In the shown embodiment, the optical waveguide in form of the internal portion 110 is physically connected with mutual overlap for evanescent field coupling with the semiconductor waveguide in form of optical input and/or output element 144 of component 122. By such a mutual overlap between (in particular horizontal) sections of the optical waveguide and the semiconductor waveguide, evanescent field coupling may be established in between, thereby highly efficiently optically coupling the optical waveguide with the optical chip. Descriptively speaking, evanescent wave coupling may describe the coupling of an electromagnetic wave from one waveguide to another by way of a decaying electromagnetic field.

It should be noted that the term “comprising” does not exclude other elements or steps and the article “a” or “an” does not exclude a plurality. Also, elements described in association with different embodiments may be combined.

Implementation of the disclosure is not limited to the preferred embodiments shown in the figures described above. Instead, a multiplicity of variants are possible which variants use the solutions shown and the principle according to the disclosure even in the case of fundamentally different embodiments.

1. A component carrier, comprising:
a stack comprising at least one electrically conductive layer structure and at least one electrically insulating layer structure; and
an at least partially optically transparent body on and/or in the stack, said at least partially optically transparent body being configured to guide light entering from or exiting to an external periphery of the at least partially optically transparent body along a predefined trajectory.

2. The component carrier according to claim 1, wherein said at least partially optically transparent body comprises an internal portion with a different refraction index with respect to that of a rest of the at least partially optically transparent body, said internal portion being configured to guide the light entering from or exiting to the external periphery of the at least partially optically transparent body along the predefined trajectory.

3. The component carrier according to claim 2, wherein the component carrier comprises at least one of the following features:
wherein the internal portion with the different refraction index defines one or more optical guiding structures exposed to the external periphery of the at least partially optically transparent body, and
wherein the internal portion with the different refraction index is configured to guide the light towards a predefined position on an external surface of the at least partially optically transparent body.

4. The component carrier according to claim 1, wherein the at least partially optically transparent body comprises a first surface via which light enters or exits and a second surface via which light exits or enters.

5. The component carrier according to claim 4, wherein the first surface and the second surface are perpendicular or inclined with respect to each other.

6. The component carrier according to claim 1, further comprising:
a deflecting member configured for deflecting the light after propagation along part of or the entire predefined trajectory.

7. The component carrier according to claim 6, wherein the component carrier comprises at least one of the following features:
wherein the deflecting member is provided in one of external surfaces of the at least partially optically transparent body,
wherein the deflecting member comprises a reflective portion provided on a surface of the at least partially optically transparent body,
wherein the deflecting member has a surface that is inclined with respect to the light guided by an internal portion with the different refraction index,
wherein the deflecting member is integrally formed with the at least partially optically transparent body,
wherein the deflecting member is provided on a surface of the at least partially optically transparent body,
wherein the light guided by an internal portion with the different refraction index is emitted towards or received from the deflecting member along a direction that is inclined with respect to a surface of the at least partially optically transparent body via which the light enters or exits and/or with respect to a surface of the at least partially optically transparent body via which the light exits or enters.

8. The component carrier according to claim 2, wherein the component carrier comprises at least one of the following features:
wherein the internal portion with the different refraction index is configured to separately guide a plurality of light signals or portions simultaneously,
wherein the component carrier comprises a deflecting member configured for deflecting all the light signals or portions, and
wherein the component carrier comprises a focusing unit configured for focusing the light guided by the internal portion with the different refraction index towards a component.

9. The component carrier according to claim 1, having an intermediate space between the at least partially optically transparent body and a component receiving or emitting the light.

10. The component carrier according to claim 9, wherein the component carrier comprises at least one of the following features:
a further at least partially optically transparent body arranged in the intermediate space,
wherein the further optically transparent body comprises at least one deflecting member and/or an internal portion with a different refraction index with respect to that of a rest of the further optically transparent body, wherein the intermediate space is an empty space, wherein the intermediate space extends from the at least partially optically transparent body to the component receiving or emitting the light,
wherein the intermediate space extends along a thickness direction of the stack,
wherein the intermediate space is formed at least partially by a cavity in the stack,
wherein the intermediate space is arranged completely inside of the stack, and
wherein the intermediate space is arranged at least partially outside of the stack.

11. The component carrier according to claim 1, wherein the component carrier comprises at least one of the following features:
at least one lens arranged in the at least partially optically transparent body and/or in the intermediate space and being configured to change a focus of the light, and
a component configured for receiving or emitting the light and being arranged externally from the stack.

12. The component carrier according to claim 1, wherein the component carrier comprises at least one of the following features:
wherein the at least partially optically transparent body is arranged in the stack,
a component configured for receiving or emitting the light and being arranged above the at least partially optically transparent body, and
a component configured for receiving or emitting the light and being arranged laterally from the at least partially optically transparent body.

13. The component carrier according to claim 12, wherein the component carrier comprises at least one of the following features:
wherein both the at least partially optically transparent body and the component, and optionally the intermediate space, are provided in the stack so that the light is transmitted by the at least partially optically transparent body and is received or emitted by the component from a side facing one to each other; and
wherein both the at least partially optically transparent body and the component are at least partially arranged in the same electrically conductive layer structure and/or electrically insulating layer structure of the stack.

14. The component carrier according to claim 1, wherein the component carrier comprises at least one of the following features:
wherein the at least partially optically transparent body is made of glass,
wherein the at least partially optically transparent body comprises an organic material, and
wherein the at least partially optically transparent body comprises at least one portion of a material different from a main body.

15. The component carrier according to claim 1, wherein the component carrier comprises at least one of the following features:
an optical connector being optically coupled with the at least partially optically transparent body at a sidewall of the component carrier, and
a component mounted on the stack and being an optical chip.

16. The component carrier according to claim 15, further comprising:
a further component electrically coupled with the component by the at least one electrically conductive layer structure,
wherein the at least one electrically conductive layer structure electrically coupling the further component with the component is arranged on and/or above the at least partially optically transparent body.

17. The component carrier according to claim 1, wherein the component carrier comprises at least one of the following features:
a further at least partially optically transparent body on and/or in the stack,
a component mounted on the stack and being in direct contact with at least a portion of the optically transparent body for evanescent light coupling between the component and the optically transparent body.

18. The component carrier according to claim 6, wherein the component carrier comprises at least one of the following features:
wherein the deflecting member is configured as constituent of the at least one electrically conductive layer structure,
wherein the deflecting member is configured as alignment marker for ensuring alignment during a manufacturing process.

19. A method of manufacturing a component carrier, the method comprising:
providing a stack comprising at least one electrically conductive layer structure and at least one electrically insulating layer structure; and
arranging an at least partially optically transparent body on and/or in the stack, said at least partially optically transparent body being configured to guide light entering from or exiting to an external periphery of the at least partially optically transparent body along a predefined trajectory.

20. The method according to claim 19, wherein the method comprises configuring an internal portion of said at least partially optically transparent body as at least one integrated waveguide by laser direct writing.
